(19) United States
(12) Patent Application Publication
(10) Pub. No.: US 2026/0025963 A1
(43) Pub. Date: Jan. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: Eun Won SEO, Yongin-si (KR); Cheul Jin PARK, Yongin-si (KR); Jun Hee SON, Yongin-si (KR); Joon Ik LEE, Yongin-si (KR)

(21) Appl. No.: 19/240,125

(22) Filed: Jun. 17, 2025

(30) Foreign Application Priority Data
Jul. 18, 2024 (KR) 10-2024-0095220

(51) Int. Cl. H05K 7/20

(52) U.S. Cl. CPC H05K 7/2099

(57) ABSTRACT

A display device includes: a display panel; a lower plate on a rear surface of the display panel; a heat dissipation layer on a rear surface of the lower plate, and including a plurality of bend portions; and a pulsating heat pipe in at least one of the bend portions.

### CROSS-REFERENCE TO RELATED APPLICATION

The present application claims priority to and the benefit of Korean Patent Application No. 10-2024-0095220, filed on Jul. 18, 2024, in the Korean Intellectual Property Office, the entire disclosure of which is incorporated by reference herein.

### BACKGROUND

### 1. Field

Aspects of embodiments of the present disclosure relate to a display device and an electronic device including the same.

### 2. Description of the Related Art

As interest in information display has been increased, research and development on a display device is continuously being conducted.

### SUMMARY

One or more embodiments of the present disclosure may be directed to a display device having an improved heat dissipation characteristic by utilizing a bend portion space of a heat dissipation plate.

However, the present disclosure is not limited to the above aspects and features, and the above and other aspects and features of the present disclosure may be more clearly understood by those having ordinary skill in the art from the following description.

According to one or more embodiments of the present disclosure, a display device includes: a display panel; a lower plate on a rear surface of the display panel; a heat dissipation layer on a rear surface of the lower plate, and including a plurality of bend portions; and a pulsating heat pipe in at least one of the bend portions.

In an embodiment, the at least one of the bend portions may be attached with the lower plate.

In an embodiment, the bend portions may include a first bend portion attached with the lower plate, and a second bend portion spaced from the lower plate.

In an embodiment, the pulsating heat pipe may be surrounded by the lower plate and the second bend portion.

In an embodiment, the first bend portion and the second bend portion may be alternately located.

In an embodiment, the first bend portion may have an opening.

In an embodiment, the display device may further include a resin in at least one of the bend portions on a rear surface of the heat dissipation layer.

In an embodiment, the resin may be directly on the rear surface of the heat dissipation layer.

In an embodiment, the resin may planarize a step of the bend portions.

In an embodiment, the heat dissipation layer may have an opening.

In an embodiment, the resin may be in contact with the lower plate through the opening.

According to one or more embodiments of the present disclosure, a display device includes: a display panel; a lower plate on a rear surface of the display panel; a heat dissipation layer including a first bend portion attached with a rear surface of the lower plate, and a second bend portion spaced from the lower plate; a heat dissipation path in the second bend portion; and a resin in the first bend portion.

In an embodiment, the first bend portion and the second bend portion may be alternately located.

In an embodiment, the first bend portion may have an opening.

In an embodiment, the resin may be in contact with the lower plate through the opening.

In an embodiment, the lower plate may include a heat-melting film.

In an embodiment, the heat dissipation path may be surrounded by the lower plate and the second bend portion.

In an embodiment, the resin may be directly on a rear surface of the heat dissipation layer.

In an embodiment, the lower plate may include a metal material.

In an embodiment, the heat dissipation layer may include a metal material.

According to one or more embodiments of the present disclosure, an electronic device includes: a display panel; a lower plate on a rear surface of the display panel; a heat dissipation layer on a rear surface of the lower plate, and comprising a plurality of bend portions; and a pulsating heat pipe in at least one of the bend portions, wherein the electronic device is one of a smartphone, a personal computer, a laptop, a personal digital assistant, a car navigation, a game console, a tablet PC, a camera, a television, a monitor, or a billboard.

In an embodiment, the at least one of the bend portions is attached with the lower plate.

In an embodiment, the bend portions comprise a first bend portion attached with the lower plate, and a second bend portion spaced from the lower plate.

According to some embodiments of the present disclosure, by forming the pulsating heat pipe by utilizing a bend portion structure of the heat dissipation plate, a heat dissipation characteristic of the display device may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a block diagram illustrating a display device according to an embodiment of the present disclosure;

FIG. 2 is a block diagram illustrating one of the sub-pixels of FIG. 1 according to an embodiment of the present disclosure;

FIG. 3 is a circuit diagram illustrating the sub-pixel of FIG. 2 according to an embodiment of the present disclosure;

FIG. 4 is a plan view illustrating a display panel of FIG. 1 according to an embodiment of the present disclosure;

FIGS. 5 and 6 are cross-sectional views illustrating a display device according to some embodiments of the present disclosure;

FIG. 7 is a cross-sectional view illustrating a display device according to an embodiment of the present disclosure;

FIG. 8 is a cross-sectional view illustrating a display device according to an embodiment of the present disclosure;

FIG. 9 is a cross-sectional view illustrating a display device according to an embodiment of the present disclosure; and

FIG. 10 is a cross-sectional view illustrating a display device according to an embodiment of the present disclosure.

FIG. 11 is a block diagram of an electronic device according to an embodiment of the present disclosure.

FIG. 12 shows schematic views of various embodiments of an electronic device.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

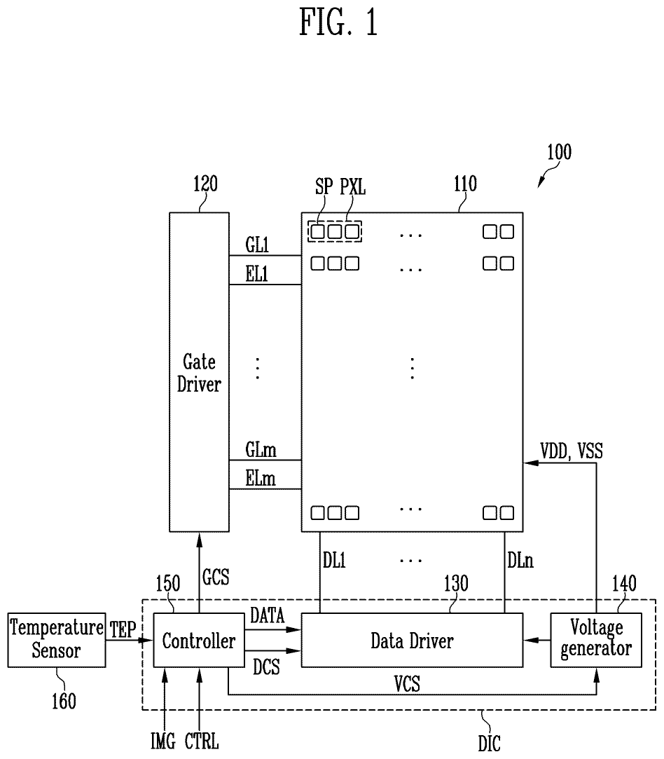

FIG. 1 is a block diagram illustrating a display device according to an embodiment of the present disclosure.

Referring to FIG. 1, the display device 100 may include a display panel 110, a gate driver 120, a data driver 130, a voltage generator 140, and/or a controller 150. The display device 100 may be implemented as any suitable electronic device, for example, such as a smartphone, a personal computer, a laptop, a personal digital assistant, a car navigation, a game console, a tablet PC, a camera, a television, a monitor, or a billboard.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, n and m may be integers greater than 1.

Each of the sub-pixels SP may include at least one light emitting element to generate light. Accordingly, each of the sub-pixels SP may generate light of a desired color (e.g., a specific or predetermined color), such as red, green, blue, cyan, magenta, or yellow. Two or more sub-pixels among the sub-pixels SP may configure one pixel PXL. For example, as shown in FIG. 1, three sub-pixels SP may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal for outputting the gate signals in synchronization with a timing at which data signals are applied, and the like.

In an embodiment, first to m-th emission control lines EL1 to ELm connected to the sub-pixels SP of the row direction may be further provided. In this case, the gate driver 120 may include an emission control driver to control the first to m-th emission control lines EL1 to EIm, and the emission control driver may operate under the control of the controller 150.

The gate driver 120 may be disposed on one side of the display panel 110. However, the present disclosure is not limited thereto. For example, the gate driver 120 may be divided into two or more physically and/or logically divided drivers, and the drivers may be disposed on one side of the display panel 110 and another side of the display panel 110 opposite the one side. As described above, the gate driver 120 may be disposed around the display panel 110 in various suitable shapes according to some embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Thus, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the components of the display device 100. For example, the voltage generator 140 may generate the plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In another embodiment, the first power voltage VDD or the second power voltage VSS may be provided by an external device of the display device 100.

In addition, the voltage generator 140 may generate various suitable voltages. For example, the voltage generator 140 may generate an initialization voltage applied to the sub-pixels SP. For example, during a sensing operation for sensing electrical characteristics of transistors and/or light emitting elements of the sub-pixels SP, a reference voltage (e.g., a predetermined reference voltage) may be applied to the first to n-th data lines DL1 to DLn, and the voltage generator 140 may generate the reference voltage.

The controller 150 may control the overall operations of the display device 100. The controller 150 may receive input image data IMG and a control signal CTRL for controlling a display of the input image data IMG from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110, and may output the image data DATA. In an embodiment, the controller 150 may output the image data DATA by aligning the input image data IMG so as to be suitable for the sub-pixels SP of a row unit (e.g., in the unit of a row).

Two or more components among the data driver 130, the voltage generator 140, and/or the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In another embodiment, at least one of the data driver 130, the voltage generator 140, or the controller 150 may be provided as a component distinguished from the driver integrated circuit DIC.

The display device 100 may include at least one temperature sensor 160. The temperature sensor 160 may sense a temperature around the temperature sensor 160, and may generate temperature data TEP indicating the sensed temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may adjust a luminance of the image output from the display panel 110 in response to the temperature data TEP. For example, the controller 150 may control the data signals and the first and second power voltages VDD and VSS by controlling the components, such as the data driver 130 and/or the voltage generator 140.

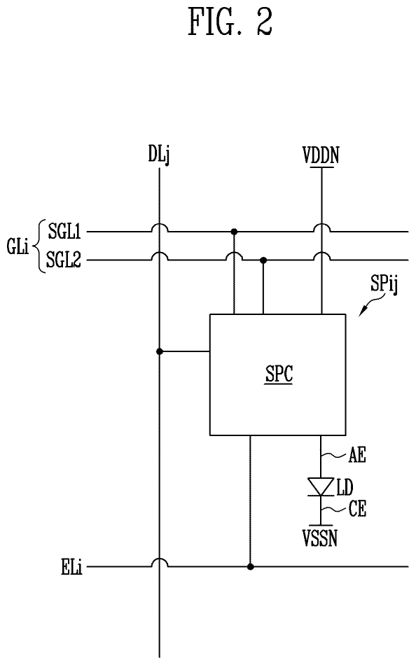

FIG. 2 is a block diagram illustrating one of the sub-pixels of FIG. 1 according to an embodiment of the present disclosure. In FIG. 2, among the sub-pixels SP of FIG. 1, a sub-pixel SPij arranged in an i-th row (where i is an integer greater than or equal to 1 and less than or equal to m) and a j-th column (where j is an integer greater than or equal to 1 and less than or equal to n) may be shown as a representative example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node that transmits the first power voltage VDD described above with reference to FIG. 1, and the second power voltage node VSSN may be a node that transmits the second power voltage VSS.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm described above with reference to FIG. 1, an i-th emission control line ELi among the first to m-th emission control lines EL1 to ELm, and a j-th data line DLj among the first to n-th data lines DL1 to DLn. The sub-pixel circuit SPC may control the light emitting element LD according to signals received through the above-described signal lines.

The sub-pixel circuit SPC may operate in response to a gate signal received through the i-th gate line GLi. The i-th gate line GLi may include one or more sub gate lines. In an embodiment, as shown in FIG. 2, the i-th gate line GLi may include first and second sub gate lines SGL1 and SGL2. The sub-pixel circuit SPC may operate in response to gate signals received through the first and second sub gate lines SGL1 and SGL2. As described above, when the i-th gate line GLi includes two or more sub-gate lines, the sub-pixel circuit SPC may operate in response to gate signals received through the two or more sub gate lines.

The sub-pixel circuit SPC may operate in response to an emission control signal received through the i-th emission control line ELi. In an embodiment, the i-th emission control line ELi may include one or more sub emission control lines. When the i-th emission control line ELi includes two or more sub emission control lines, the sub-pixel circuit SPC may operate in response to emission control signals received through the two or more sub emission control lines.

The sub-pixel circuit SPC may receive a data signal through the j-th data line DLj. The sub-pixel circuit SPC may store a voltage corresponding to the data signal in response to at least one of the gate signals received through the first and second sub gate lines SGL1 and SGL2. The sub-pixel circuit SPC may adjust a current flowing from the first power voltage node VDDN to the second power voltage node VSSN through the light emitting element LD according to the stored voltage, in response to the emission control signal received through the i-th emission control line ELi. Accordingly, the light emitting element LD may generate light having a luminance corresponding to the data signal.

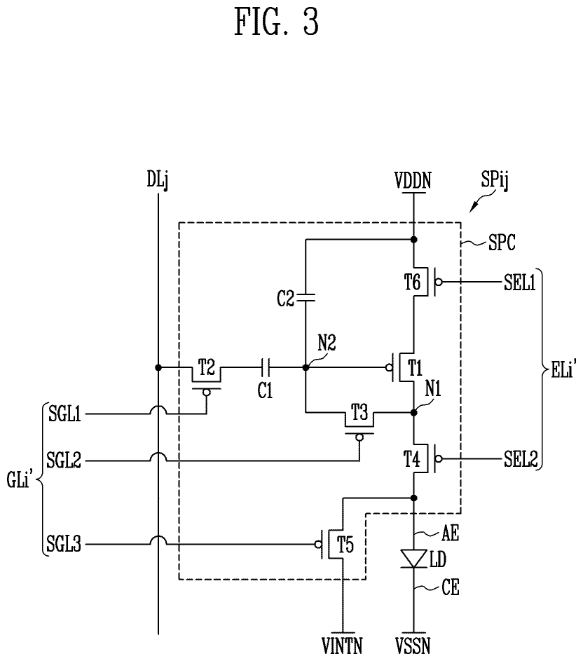

FIG. 3 is a circuit diagram illustrating the sub-pixel of FIG. 2 according to an embodiment of the present disclosure.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and the j-th data line DLj. Compared to the i-th gate line GLi described above with reference to FIG. 2, the i-th gate line GLi′ may further include a third sub gate line SGL3. Compared to the i-th emission control line ELi described above with reference to FIG. 2, the i-th emission control line ELi′ may include a first sub emission control line SEL1 and a second sub emission control line SEL2.

The sub-pixel circuit SPC may include first to sixth transistors T1 to T6, and first and second capacitors C1 and C2.

The first transistor T1 may be connected between the first power voltage node VDDN and a first node N1. A gate of the first transistor T1 may be connected to a second node N2, and thus, the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub gate line SGL1, and thus, the second transistor T2 may be turned on in response to a gate signal of the first sub gate line SGL1. The second transistor T2 may be referred to as a switching transistor.

The third transistor T3 may be connected between the first node N1 and the second node N2. A gate of the third transistor T3 may be connected to the second sub gate line SGL2, and thus, the third transistor T3 may be turned on in response to a gate signal of the second sub gate line SGL2.

The fourth transistor T4 may be connected between the first node N1 and the anode electrode AE of the light emitting element LD. A gate of the fourth transistor T4 may be connected to the second sub emission control line SEL2, and thus, the fourth transistor T4 may be turned on in response to an emission control signal of the second sub emission control line SEL2.

The fifth transistor T5 may be connected between the anode electrode AE of the light emitting element LD and an initialization voltage node VINTN. The initialization voltage node VINTN may transmit an initialization voltage. In an embodiment, the initialization voltage may be provided by the voltage generator 140 described above with reference to FIG. 1. In another embodiment, the initialization voltage may be provided by an external device of the display device 100. A gate of the fifth transistor T5 may be connected to the third sub gate line SGL3, and thus, the fifth transistor T5 may be turned on in response to a gate signal of the third sub gate line SGL3.

The sixth transistor T6 may be connected between the first power voltage node VDDN and the first transistor T1. A gate of the sixth transistor T6 may be connected to the first sub emission control line SEL1, and thus, the sixth transistor T6 may be turned on in response to an emission control signal of the first sub emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, the present disclosure is not limited thereto. The sub-pixel circuit SPC may be implemented as one of various suitable kinds of circuits including a plurality of transistors and one or more capacitors. For example, the sub-pixel circuit SPC may include two transistors and one capacitor. According to some embodiments, the number of sub gate lines included in the i-th gate line GLi′ and the number of sub emission control lines included in the i-th emission control line ELi′ may also be variously modified.

The first to sixth transistors T1 to T6 may be P-type transistors. Each of the first to sixth transistors T1 to T6 may be a metal oxide silicon field effect transistor (MOSFET). However, the present disclosure is not limited thereto. For example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, the cathode electrode CE, and a light emitting layer. The light emitting layer may be disposed between the anode electrode AE and the cathode electrode CE. After the data signal transmitted through the j-th data line DLj is reflected in the voltage of the second node N2, when the emission control signals of the first and second sub emission control lines SEL1 and SEL2 are enabled to a low level, the fourth and sixth transistors T4 and T6 may be turned on. The first transistor T1 may be turned on according to the voltage of the second node N2, and thus, a current may flow from the first power voltage node VDDN to the second power voltage node VSSN. The light emitting element LD may emit light according to the flowing current.

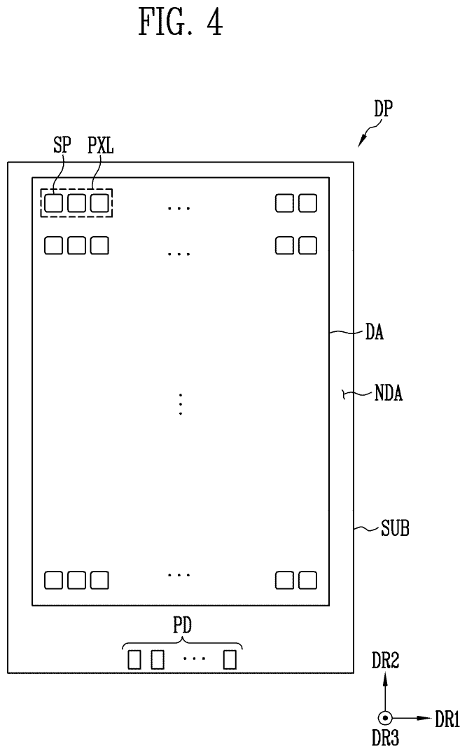

FIG. 4 is a plan view illustrating the display panel of FIG. 1 according to an embodiment of the present disclosure.

Referring to FIG. 4, the display panel DP may be an embodiment of the display panel 110 described above with reference to FIG. 1, and may include the display area DA and a non-display area NDA. The display panel DP may display an image through the display area DA. The non-display area NDA may be disposed around the display area DA.

The display panel DP may include a substrate SUB, the sub-pixels SP, and/or pads PD. In an embodiment, the display panel DP may have a flexibility. For example, the display panel DP may be bendable, foldable, or rollable. For example, the display device 100 may be a flexible display device. In this case, the substrate SUB may be formed of a flexible material. For example, the substrate SUB may be one of a film substrate or a plastic substrate including a polymer organic material. The substrate SUB may include at least one of polystyrene, polyvinyl alcohol, polymethyl methacrylate, polyether sulfone, polyacrylate, polyether imide, polyethylene naphthalate, polyethylene terephthalate, polyphenylene sulfide, polyarylate, polyimide, polycarbonate, triacetate cellulose, or cellulose acetate propionate, but the present disclosure is not necessarily limited thereto.

The sub-pixels SP may be disposed in the display area DA on the substrate SUB. The sub-pixels SP may be arranged in a matrix shape along a first direction DR1 and a second direction DR2 crossing the first direction DR1. However, the present disclosure is not limited thereto. For example, the sub-pixels SP may be arranged in a zigzag shape along the first direction DR1 and the second direction DR2. For example, the sub-pixels SP may be arranged in a diamond shape (e.g., a PENTILE® shape, PENTILE® being a duly registered trademark of Samsung Display Co., Ltd.). The first direction DR1 may be a row direction, and the second direction DR2 may be a column direction. Two or more sub-pixels among the plurality of sub-pixels SP may configure one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn described above with reference to FIG. 1, may be disposed in the non-display area NDA.

At least one of the gate driver 120, the data driver 130, the voltage generator 140, the controller 150, or the temperature sensor 160 described above with reference to FIG. 1 may be integrated in the non-display area NDA of the display panel DP. In an embodiment, the gate driver 120 described above with reference to FIG. 1 may be mounted on the display panel DP, and may be disposed in the non-display area NDA. In another embodiment, the gate driver 120 may be implemented as an integrated circuit separated from the display panel DP. In an embodiment, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through some of the lines. For example, the pads PD may be connected to the sub-pixels SP through the first to n-th data lines DL1 to DLn.

The pads PD may interface the display panel DP to other components of the display device 100. In an embodiment, voltages and signals used for an operation of the components included in the display panel DP may be provided from the driver integrated circuit DIC described above with reference to FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

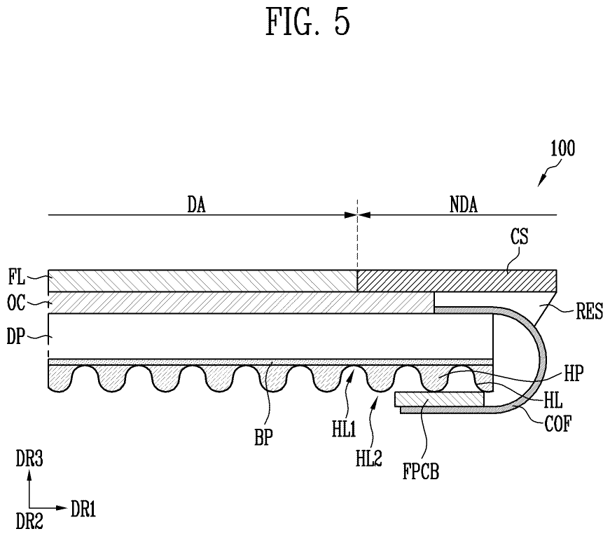

In an embodiment, the driver integrated circuit DIC may be mounted on a flexible circuit board FPCB (e.g., see FIG. 5), and may be electrically connected to the pads PD. The flexible circuit board FPCB may be electrically connected to the pads PD using a conductive adhesive material, such as an anisotropic conductive film.

In an embodiment, the display area DA may have various suitable shapes. The display area DA may have a closed loop shape including straight and/or curved sides. For example, the display area DA may have various suitable shapes, such as a polygon, a circle, a semicircle, or an ellipse.

In an embodiment, the display panel DP may have a flat or substantially flat display surface. In another embodiment, the display panel DP may have a display surface that is at least partially round or rounded.

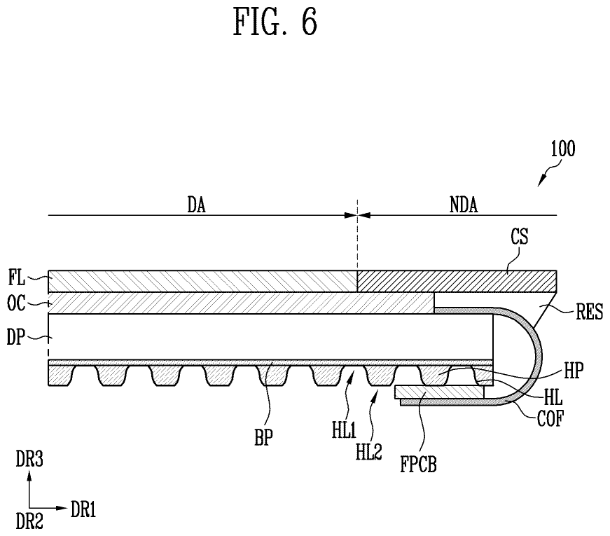

FIGS. 5 and 6 are cross-sectional views illustrating a display device according to some embodiments of the present disclosure.

Referring to FIGS. 5 and 6, the display device 100 may include a display panel DP, a lower plate BP, a heat dissipation layer HL, an overcoat layer OC, an optical layer FL, a resin portion RES, a chip on film COF, the flexible printed circuit board FPCB, and/or a cover portion CS.

The lower plate BP may be disposed on a rear surface of the display panel DP. The lower plate BP may be directly disposed on the rear surface of the display panel DP. The lower plate BP may serve to form a heat dissipation path (e.g., a pulsating heat pipe) HP together with the heat dissipation layer HL. For example, the lower plate BP may form one surface of the heat dissipation path HP.

The lower plate BP may include a metal material having a high thermal conductivity so as to absorb and release heat. For example, the lower plate BP may include copper, aluminum, silver, molybdenum, tungsten, zinc, and/or the like, but the present disclosure is not necessarily limited thereto.

The heat dissipation layer HL may be disposed on a rear surface of the lower plate BP. The heat dissipation layer HL may be directly disposed on the rear surface of the lower plate BP. The heat dissipation layer HL may include successive bend portions HL1 and HL2. At least one bend portion HL1 or HL2 may be combined with the lower plate BP. For example, the first bend portions HL1 may be combined with the rear surface of the lower plate BP. In an embodiment, the lower plate BP and the first bend portions HL1 may be joined to each other by a laser or welding, but the present disclosure is not necessarily limited thereto. The second bend portions HL2 may be spaced apart from the lower plate BP. The first bend portions HL1 and the second bend portions HL2 may be alternately disposed.

The bend portions HL1 and HL2 of the heat dissipation layer HL may have a shape that is bent in a wave shape or an S shape, as shown in FIG. 5. However, the present disclosure is not necessarily limited thereto, and the bend portions HL1 and HL2 of the heat dissipation layer HL may have various suitable bend shapes, such as a trapezoidal shape or a rectangular shape, as shown in FIG. 6.

The heat dissipation path HP may be formed by utilizing the bend portions HL1 and HL2 of the heat dissipation layer HL. The heat dissipation path HP may be positioned between the lower plate BP and the heat dissipation layer HL. For example, the heat dissipation path HP may be positioned between the rear surface of the lower plate BP and an upper surface of the heat dissipation layer HL. The heat dissipation path HP may refer to a space surrounded (e.g., around a periphery thereof) by the rear surface of the lower plate BP and the upper surface of the heat dissipation layer HL.

The heat dissipation path HP may be positioned in the second bend portion HL2 of the heat dissipation layer HL. For example, the heat dissipation path HP may refer to a space surrounded (e.g., around a periphery thereof) by the lower plate BP and the second bend portion HL2 of the heat dissipation layer HL.

The heat dissipation path HP may serve to provide a path through which a coolant may circulate. The coolant may diffuse or cool heat emitted from the display panel DP through a space formed by the bend portions HL1 and HL2, or in other words, the heat dissipation path HP, thereby preventing heat from being concentrated in a specific portion of the display device 100, and improving heat dissipation performance.

In an embodiment, the heat dissipation layer HL may efficiently circulate heat by utilizing a phase change of the coolant. For example, the coolant injected into an inside of a vacuum-sealed heat dissipation path HP may absorb heat in a high temperature portion, vaporize, and then move to a low temperature portion and condense to emit heat, thereby rapidly transferring heat. For example, the heat dissipation path HP may be a pulsating heat pipe (PHP) having a liquid and gas that self-pulsate, and may transfer heat of an evaporation portion to a condensation portion, but the present disclosure is not necessarily limited thereto. In an embodiment, the coolant may be directly introduced into a space surrounded (e.g., around a periphery thereof) by the heat dissipation layer HL and the second bend portion HL2 of the lower plate BP. The coolant may be surrounded (e.g., around a periphery thereof) by the rear surface of the lower plate BP and the upper surface of the heat dissipation layer HL. In an embodiment, a general coolant or refrigerant gas may be applied as the coolant, but may be variously modified as needed or desired.

In an embodiment, the heat dissipation layer HL may further include a coolant temperature controller, a mass flow controller, and/or the like. The coolant temperature controller may serve to control a temperature of the coolant injected into the heat dissipation path HP. The mass flow controller may serve to measure and control a flow rate of the coolant injected into the heat dissipation path HP. However, the present disclosure is not limited thereto, and the coolant temperature controller and/or the mass flow controller may be omitted as needed or desired.

In an embodiment, the heat dissipation layer HL may include a metal material having a high thermal conductivity so as to be able to absorb and release heat. For example, the heat dissipation layer HL may include copper, aluminum, silver, molybdenum, tungsten, zinc, and/or the like, but the present disclosure is not necessarily limited thereto.

The overcoat layer OC may be disposed on the display panel DP. The overcoat layer OC may be disposed on an upper surface of the display panel DP to cover the display panel DP. The overcoat layer OC may be disposed in the display area DA. The overcoat layer OC may include various materials suitable for protecting the lower layers therefrom from a foreign substance, such as dust or moisture. For example, the overcoat layer OC may include at least one of an inorganic insulating layer or an organic insulating layer. For example, the overcoat layer OC may include an epoxy, but the present disclosure is not limited thereto.

The optical layer FL may be disposed on the overcoat layer OC. The optical layer FL may be disposed on an upper surface of the overcoat layer OC. The optical layer FL may be disposed in the display area DA. The optical layer FL may include a low-reflection film, a polarizing film, a transparent plastic film, and/or the like, but the present disclosure is not necessarily limited thereto.

The resin portion RES may be disposed in an outer portion of the display panel DP. The resin portion RES may cover the overcoat layer OC and the chip on film COF. The resin portion RES may cover a side surface of the display panel DP. For example, the resin portion RES may be disposed on one side of the display device 100 on which the chip on film COF and the flexible printed circuit board FPCB are disposed, thereby reducing an influence of dust and moisture on the display device 100. The resin portion RES may include one of an epoxy resin or an acrylic resin, but the present disclosure is not necessarily limited thereto.

The resin portion RES may be disposed under the cover portion CS. The resin portion RES may be disposed between the cover portion CS and the chip on film COF. The resin portion RES may be disposed between the cover portion CS and the overcoat layer OC. The resin portion RES may be disposed in the non-display area NDA. The resin portion RES may not overlap with the optical layer FL in a third direction DR3, but the present disclosure is not necessarily limited thereto.

One end of the chip on film COF may be connected (e.g., may be attached) to the display panel DP, and another end of the chip on film COF may be connected (e.g., may be attached) to the flexible printed circuit board FPCB. The chip on film COF may be at least partially bent.

The chip on film COF may provide an electrical signal obtained based on a signal applied from the flexible printed circuit board FPCB to the display panel DP. The chip on film COF may include an insulating film, and lines provided on the insulating film

In an embodiment, an adhesive member may be further disposed between the chip on film COF and the display panel DP. The adhesive member may combine the chip on film COF and the display panel DP to each other. The adhesive member may include a conductive material to electrically connect lines of the display panel DP and the chip on film COF to each other. For example, the adhesive member may be an anisotropic conductive film, but the present disclosure is not necessarily limited thereto.

A circuit element to process an electrical signal that may be applied to the display panel DP may be disposed on the flexible printed circuit board FPCB. The flexible printed circuit board FPCB may be disposed on one surface or a rear surface of the display panel DP. For example, the flexible printed circuit board FPCB may be disposed on one surface or the rear surface of the heat dissipation layer HL. For example, the flexible printed circuit board FPCB may be connected to the chip on film COF, and may be disposed on the rear surface of the display panel DP or the heat dissipation layer HL.

The cover portion CS may be disposed on one side of the display panel DP. The cover portion CS may be disposed on an outer portion of the display panel DP. The cover portion CS may be disposed in the non-display area NDA. The cover portion CS may overlap with the chip on film COF and/or the flexible printed circuit board FPCB in the third direction DR3. In an embodiment, the cover portion CS may include a metal material. For example, the cover portion CS may include aluminum, magnesium, and/or the like, but the present disclosure is not necessarily limited thereto.

According to an embodiment, the heat dissipation characteristic of the display device 100 may be improved by forming the heat dissipation path (e.g., the pulsating heat pipe) HP by utilizing the bent portions HL1 and HL2 of the heat dissipation layer HL. Accordingly, heat dissipation of the display device 100 may be improved, and a flexible characteristic of the display device 100 may be improved by reducing a thickness and a weight of a product.

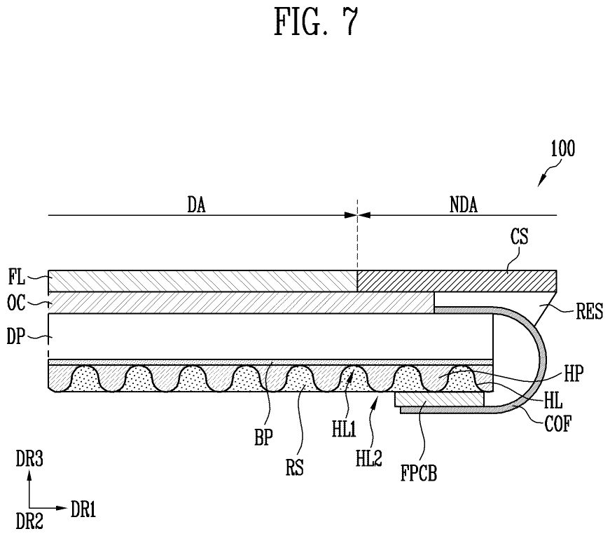

Hereinafter, some other embodiments may be described in more detail with reference to FIGS. 7 to 10. In FIGS. 7 to 10, the same or substantially the same components and configurations as those described above are denoted by the same reference numerals, and thus, redundant description may be simplified, or may not be repeated.

FIG. 7 is a cross-sectional view illustrating a display device according to an embodiment of the present disclosure.

Referring to FIG. 7, a resin RS may be further disposed on the rear surface of the heat dissipation layer HL. The resin RS may be directly disposed on the rear surface of the heat dissipation layer HL. The resin RS may be provided in at least one of the bend portions HL1 or HL2. For example, the resin RS may be provided in the first bend portions HL1. The resin RS may be disposed on the rear surface of the heat dissipation layer HL to improve a flexible characteristic of the display device 100, and planarize or substantially planarize a step due to the bend portions HL1 and HL2 of the heat dissipation layer HL. In an embodiment, the resin RS may include a filler exhibiting a heat dissipation property dispersed in a polymer resin, but the present disclosure is not necessarily limited thereto. The flexible printed circuit board FPCB may be disposed on one surface or a rear surface of the resin RS. For example, the flexible printed circuit board FPCB may be connected to the chip on film COF, and may be disposed on the rear surface of the resin RS.

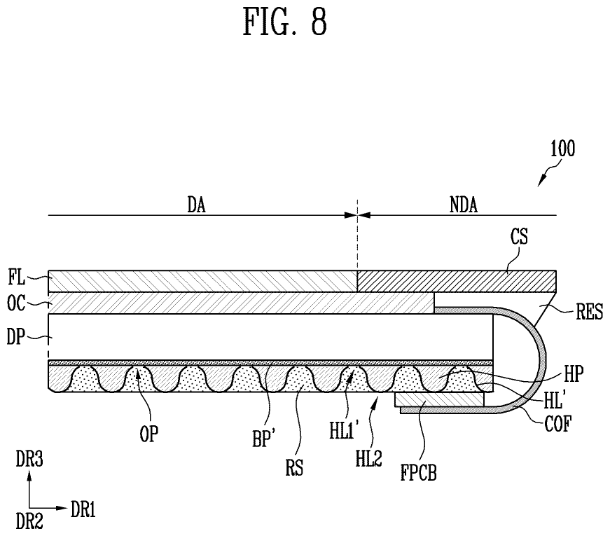

FIG. 8 is a cross-sectional view illustrating a display device according to an embodiment of the present disclosure.

Referring to FIG. 8, a heat dissipation layer HL′ may include an opening OP. For example, a first bend portion HL1′ of the heat dissipation layer HL′ may include the opening OP. The opening OP may expose a rear surface of a lower plate BP′. The resin RS may be in contact with the rear surface of the lower plate BP′ through the opening OP. In an embodiment, the lower plate BP′ may include a polymer resin. For example, the lower plate BP′ may be a flexible curable film, but the present disclosure is not necessarily limited thereto. In an embodiment, the lower plate BP′ and the resin RS may be joined to each other through UV curing, but the present disclosure is not necessarily limited thereto.

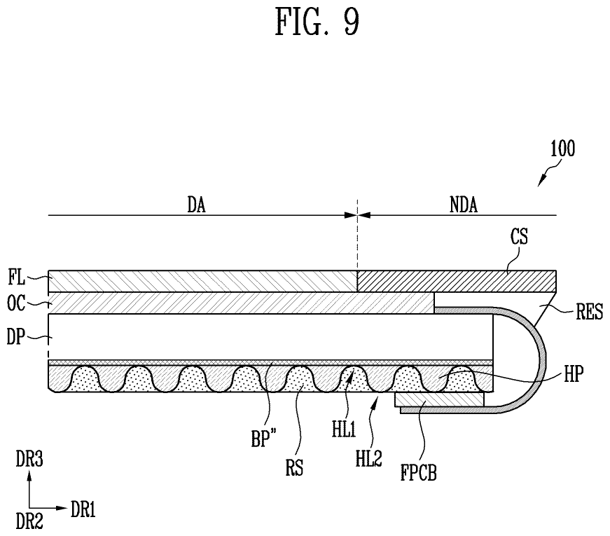

FIG. 9 is a cross-sectional view illustrating a display device according to an embodiment of the present disclosure.

Referring to FIG. 9, a lower plate BP″ may be a heat-melting film. In an embodiment, the lower plate BP″ and the heat dissipation layer HL may be joined to each other through heat-melting, but the present disclosure is not necessarily limited thereto.

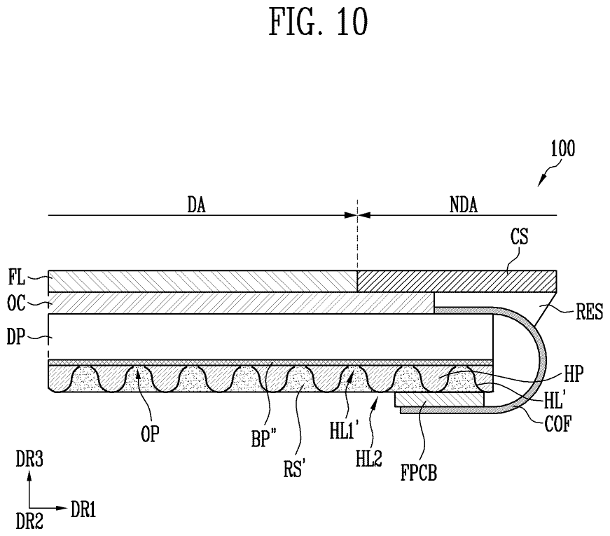

FIG. 10 is a cross-sectional view illustrating a display device according to an embodiment of the present disclosure.

Referring to FIG. 10, the heat dissipation layer HL′ may include the opening OP. For example, a first bend portion HL1′ of the heat dissipation layer HL′ may include the opening OP. The opening OP may expose a rear surface of the lower plate BP″. In an embodiment, the lower plate BP″ may be a heat-melting film. A resin RS′ may be a heat-melting resin. The resin RS′ may be in contact with a rear surface of the lower plate BP″ through the opening OP. In an embodiment, the lower plate BP″ and the resin RS′ may be joined to each other through heat-melting, but the present disclosure is not necessarily limited thereto.

A display device according to an embodiment is applicable to various types of electronic devices. In an embodiment, an electronic device includes the above-described display device and may further include other modules or devices having additional functions in addition to the display device.

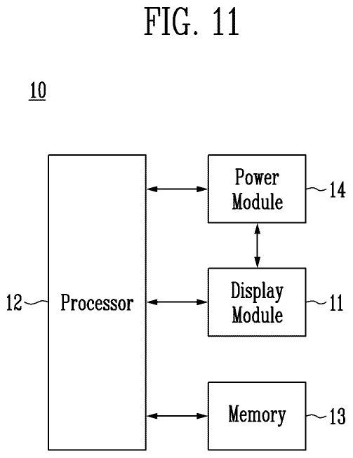

FIG. 11 is a block diagram of an electronic device according to an embodiment. Referring to FIG. 11, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above.

In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

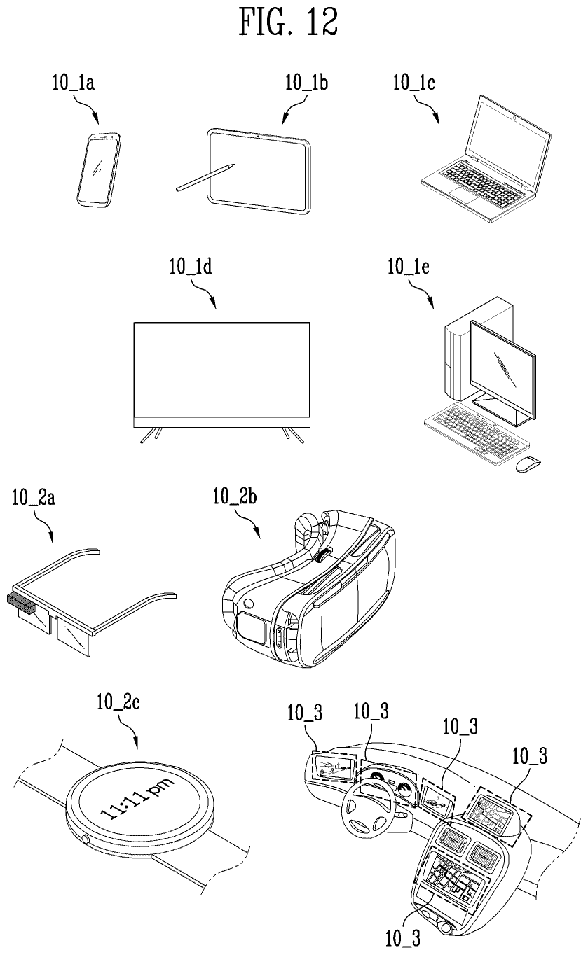

FIG. 12 shows schematic views of various embodiments of an electronic device.

Referring to FIG. 12, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel;
a lower plate on a rear surface of the display panel;
a heat dissipation layer on a rear surface of the lower plate, and comprising a plurality of bend portions; and
a pulsating heat pipe in at least one of the bend portions.

2. The display device according to claim 1, wherein the at least one of the bend portions is attached with the lower plate.

3. The display device according to claim 1, wherein the bend portions comprise a first bend portion attached with the lower plate, and a second bend portion spaced from the lower plate.

4. The display device according to claim 3, wherein the pulsating heat pipe is surrounded by the lower plate and the second bend portion.

5. The display device according to claim 3, wherein the first bend portion and the second bend portion are alternately located.

6. The display device according to claim 3, wherein the first bend portion has an opening.

7. The display device according to claim 1, further comprising:
a resin in at least one of the bend portions on a rear surface of the heat dissipation layer.

8. The display device according to claim 7, wherein the resin is directly on the rear surface of the heat dissipation layer.

9. The display device according to claim 7, wherein the resin planarizes a step of the bend portions.

10. The display device according to claim 7, wherein the heat dissipation layer has an opening.

11. The display device according to claim 10, wherein the resin is in contact with the lower plate through the opening.

12. A display device comprising:
a display panel;
a lower plate on a rear surface of the display panel;
a heat dissipation layer comprising a first bend portion attached with a rear surface of the lower plate, and a second bend portion spaced from the lower plate;
a heat dissipation path in the second bend portion; and
a resin in the first bend portion.

13. The display device according to claim 12, wherein the first bend portion and the second bend portion are alternately located.

14. The display device according to claim 12, wherein the first bend portion has an opening.

15. The display device according to claim 14, wherein the resin is in contact with the lower plate through the opening.

16. The display device according to claim 12, wherein the heat dissipation path is surrounded by the lower plate and the second bend portion.

17. The display device according to claim 12, wherein the resin is directly on a rear surface of the heat dissipation layer.

18. The display device according to claim 12, wherein the lower plate comprises a metal material.

19. The display device according to claim 12, wherein the heat dissipation layer comprises a metal material.

20. An electronic device comprising:
a display panel;
a lower plate on a rear surface of the display panel;
a heat dissipation layer on a rear surface of the lower plate, and comprising a plurality of bend portions; and
a pulsating heat pipe in at least one of the bend portions,
wherein the electronic device is one of a smartphone, a personal computer, a laptop, a personal digital assistant, a car navigation, a game console, a tablet PC, a camera, a television, a monitor, or a billboard.
